(19) United States
(12) Patent Application Publication
(10) Pub. No.: US 2024/0210596 A1
(43) Pub. Date: Jun. 27, 2024

(54) ELECTRONIC DEVICE WITH LENS ASSEMBLY AND LENS

(71) Applicant: SAMSUNG ELECTRO-MECHANICS CO., LTD., Suwon-si (KR)

(72) Inventors: Jin Woo YI, Suwon-si (KR); Sung Jun LEE, Suwon-si (KR); Tae Kyung LEE, Suwon-si (KR); Sung Sun KIM, Suwon-si (KR); Young Kyo JUNG, Suwon-si (KR)

(73) Assignee: SAMSUNG ELECTRO-MECHANICS CO., LTD., Suwon-si (KR)

(21) Appl. No.: 18/510,845

(22) Filed: Nov. 16, 2023

(30) Foreign Application Priority Data
Dec. 22, 2022 (KR) 10-2022-0181339

(51) Int. Cl. G02B 1/11

(52) U.S. Cl. CPC G02B 1/11

(57) ABSTRACT

A lens includes a lens unit; an anti-reflective (AR) coating layer, disposed on one surface of the lens unit, including a first coating layer and a second coating layer alternately stacked one or more times, wherein a refractive index of the first coating layer is different from a refractive index of the second coating layer; and an intermediate layer, disposed between the lens unit and the AR coating layer, is formed of a same material as the first coating layer or the second coating layer. The intermediate layer is disposed on the lens unit by chemical vapor deposition (CVD).

### CROSS-REFERENCE TO RELATED APPLICATIONS

This application claims the benefit under 35 USC § 119(a) of Korean Patent Application No. 10-2022-0181339, filed on Dec. 22, 2022, in the Korean Intellectual Property Office, the entire disclosure of which is incorporated herein by reference for all purposes.

### BACKGROUND

### 1. Field

The following description relates to an electronic device with a lens assembly and lens.

### 2. Description of the Background

As the functions of cameras in portable electronic devices such as mobile phones, tablet PCs, and notebook PCs become advanced, the technology of lenses used therein has also advanced.

A lens serves to focus or disperse light. With these characteristics, the lens can magnify or reduce the size of an image, and a typical characteristic of the lens is to use propagation and refraction characteristics of light.

By using these two characteristics, the size of the image of light passing through the lens can be magnified or reduced. In addition, since a view through the lens is different from an actual field of view, a lens that can capture a wider or more magnified view than what the human eye sees is used for the camera.

However, in a process in which light is refracted, the light is not focused on one point, but spreads or distorts, which is called aberration.

Aberrations can distort the image of a lens when capturing an image and affect sharpness, resulting in lower resolution.

To compensate for this problem, a combination structure of various lenses is used, and aberration correction can be performed by combining various lenses used in the camera.

However, a problem in which the light incident on the lens causes internal reflection on a surface or an inner wall of the lens may occur.

Such light may cause a flare phenomenon on a screen, and in order to prevent such a phenomenon, it may be desired to minimize light transmittance and light reflectance in a visible light region.

Accordingly, a physical vapor deposition (PVD) coating method may be used to form an anti-reflection coating (ARC) so that a problem of adhesion between the lens and the ARC may not occur, but when an intermediate layer, formed of a different material, is deposited between the lens and the ARC, a problem may occur in optical properties, due to a complex refractive index structure between the anti-reflection (AR) coating layer and the lens.

In order to solve this problem, an ALD (Atomic Layer Deposition) coating method may be applied instead of the PVD. In this case, a problem may occur in the adhesion between the lens and the AR coating layer due to a limitation in usable reactive gas.

In order to solve this problem, an anti-reflection (AR) coating layer is applied, and the existing AR coating layer is multi-layered with materials such as SiO₂ and TiO₂ to realize low reflection.

Recently, a technology for implementing an ultra-low-reflective coating layer using a nano-sized porous structure coating has been developed.

The PVD was used as a technique for depositing AR on the existing lens, but in the case of a camera for the latest mobile phone, as the size of the camera module is reduced and a degree of inclination of a curved surface of the lens becomes severe, and a difference in coating thickness between a central portion and an inclined portion increases, an ALD deposition method is adopted, which enables uniform coating on complex shapes.

However, when the ALD method is applied, there is a limitation in the material deposition that can implement AR, and there is a problem in that adhesion at an interface of the lens and the AR coating layer is weak.

In addition, an intermediate layer is required to improve adhesion, a material of such an intermediate layer is limited, and is formed of a material, different from the material used for the AR coating layer (especially a lowermost layer of the AR coating layer), resulting in deterioration in optical properties.

The above information is presented as background information only to assist with an understanding of the present disclosure. No determination has been made, and no assertion is made, as to whether any of the above might be applicable as prior art with regard to the disclosure.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, a lens includes a lens unit; an anti-reflective (AR) coating layer, disposed on one surface of the lens unit, including a first coating layer and a second coating layer alternately stacked one or more times, wherein a refractive index of the first coating layer is different from a refractive index of the second coating layer; and an intermediate layer, disposed between the lens unit and the AR coating layer, is formed of a same material as the first coating layer or the second coating layer. The intermediate layer is disposed on the lens unit by chemical vapor deposition (CVD).

The first coating layer may be formed by depositing SiO₂ using Atomic Layer Deposition (ALD), and the second coating layer may be formed by depositing Al₂O₃ using ALD.

The intermediate layer may have a thickness of 10 to 20 nm.

A lens assembly may include a plurality of lenses in an optical axis direction and an outermost lens of the plurality of lenses may include the lens described above.

A portable electronic device including a display unit may be configured to show information from the lens assembly.

A lens assembly including a plurality of lenses in an optical axis direction, wherein at least one lens of the plurality of lenses may include the lens described above.

In another general aspect, a lens assembly including at least one lens, the at least one lens including: a lens unit; an anti-reflective (AR) coating layer, disposed on one surface of the lens unit, comprising a first coating layer and a second coating layer alternately stacked one or more times, wherein a refractive index of the first coating layer is different from a refractive index of the second coating layer; and an intermediate layer, disposed between the lens unit and the AR coating layer, is formed of a same material as the first coating layer or the second coating layer. The intermediate layer is disposed on the lens unit by chemical vapor deposition (CVD).

The first coating layer may be formed by depositing SiO₂ using Atomic Layer Deposition (ALD), and the second coating layer may be formed by depositing Al₂O₃ using ALD.

The intermediate layer may have a thickness of 10 to 20 nm.

The least one lens may be disposed on an outermost side of the lens assembly in an optical axis direction of the at least one lens.

In another general aspect, a portable electronic device including a display unit configured to show information from a lens assembly, the lens assembly including at least one lens, and the at least one lens including: a lens unit; an anti-reflective (AR) coating layer, disposed on one surface of the lens unit, including a first coating layer and a second coating layer alternately stacked one or more times, wherein a refractive index of the first coating layer is different from a refractive index of the second coating layer; and an intermediate layer, disposed between the lens unit and the AR coating layer, is formed of a same material as the first coating layer or the second coating layer. The intermediate layer is disposed on the lens unit by chemical vapor deposition (CVD).

The at least one lens may be disposed on an outermost side of the lens assembly in an optical axis direction of the at least one lens.

The lens assembly may be covered by the display unit.

The lens assembly may be covered by tempered glass.

Other features and aspects will be apparent from the following detailed description, the drawings, and the claims

### BRIEF DESCRIPTION OF DRAWINGS

FIG. 1 is a perspective view schematically illustrating an example of a lens according to an embodiment of the present disclosure.

FIG. 2 is a cross-sectional view illustrating an enlarged region of the lens of FIG. 1.

FIG. 3 is a cutaway perspective view schematically illustrating an example of a lens assembly.

FIGS. 4 and 5 are perspective views schematically illustrating an example of a portable electronic device, respectively illustrating a front portion and a rear portion.

FIGS. 6 and 7 are cross-sectional views illustrating enlarged peripheral regions of the lens assembly in FIGS. 4 and 5, respectively.

Throughout the drawings and the detailed description, unless otherwise described or provided, the same drawing reference numerals may be understood to refer to the same or like elements, features, and structures. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences within and/or of operations described herein are merely examples, and are not limited to those set forth herein, but may be changed as will be apparent after an understanding of the disclosure of this application, except for sequences within and/or of operations necessarily occurring in a certain order. As another example, the sequences of and/or within operations may be performed in parallel, except for at least a portion of sequences of and/or within operations necessarily occurring in an order, e.g., a certain order. Also, descriptions of features that are known after an understanding of the disclosure of this application may be omitted for increased clarity and conciseness.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application. The use of the term “May” herein with respect to an example or embodiment, e.g., as to what an example or embodiment may include or implement, means that at least one example or embodiment exists where such a feature is included or implemented, while all examples are not limited thereto.

Throughout the specification, when a component or element is described as being “on”, “connected to,” “coupled to,” or “joined to” another component, element, or layer it may be directly (e.g., in contact with the other component or element) “on”, “connected to,” “coupled to,” or “joined to” the other component, element, or layer or there may reasonably be one or more other components, elements, layers intervening therebetween. When a component or element is described as being “directly on”, “directly connected to,” “directly coupled to,” or “directly joined” to another component or element, there can be no other elements intervening therebetween. Likewise, expressions, for example, “between” and “immediately between” and “adjacent to” and “immediately adjacent to” May also be construed as described in the foregoing.

Although terms such as “first,” “second,” and “third”, or A, B, (a), (b), and the like may be used herein to describe various members, components, regions, layers, or sections, these members, components, regions, layers, or sections are not to be limited by these terms.

Each of these terminologies is not used to define an essence, order, or sequence of corresponding members, components, regions, layers, or sections, for example, but used merely to distinguish the corresponding members, components, regions, layers, or sections from other members, components, regions, layers, or sections. Thus, a first member, component, region, layer, or section referred to in the examples described herein may also be referred to as a second member, component, region, layer, or section without departing from the teachings of the examples.

The terminology used herein is for describing various examples only and is not to be used to limit the disclosure. The articles “a,” “an,” and “the” are intended to include the plural forms as well, unless the context clearly indicates otherwise. As non-limiting examples, terms “comprise” or “comprises,” “include” or “includes,” and “have” or “has” specify the presence of stated features, numbers, operations, members, elements, and/or combinations thereof, but do not preclude the presence or addition of one or more other features, numbers, operations, members, elements, and/or combinations thereof, or the alternate presence of an alternative stated features, numbers, operations, members, elements, and/or combinations thereof. Additionally, while one embodiment may set forth such terms “comprise” or “comprises,” “include” or “includes,” and “have” or “has” specify the presence of stated features, numbers, operations, members, elements, and/or combinations thereof, other embodiments may exist where one or more of the stated features, numbers, operations, members, elements, and/or combinations thereof are not present.

Due to manufacturing techniques and/or tolerances, variations of the shapes shown in the drawings may occur. Thus, the examples described herein are not limited to the specific shapes shown in the drawings, but include changes in shape that occur during manufacturing.

Unless otherwise defined, all terms, including technical and scientific terms, used herein have the same meaning as commonly understood by one of ordinary skill in the art to which this disclosure pertains specifically in the context on an understanding of the disclosure of the present application. Terms, such as those defined in commonly used dictionaries, are to be interpreted as having a meaning that is consistent with their meaning in the context of the relevant art and specifically in the context of the disclosure of the present application, and are not to be interpreted in an idealized or overly formal sense unless expressly so defined herein.

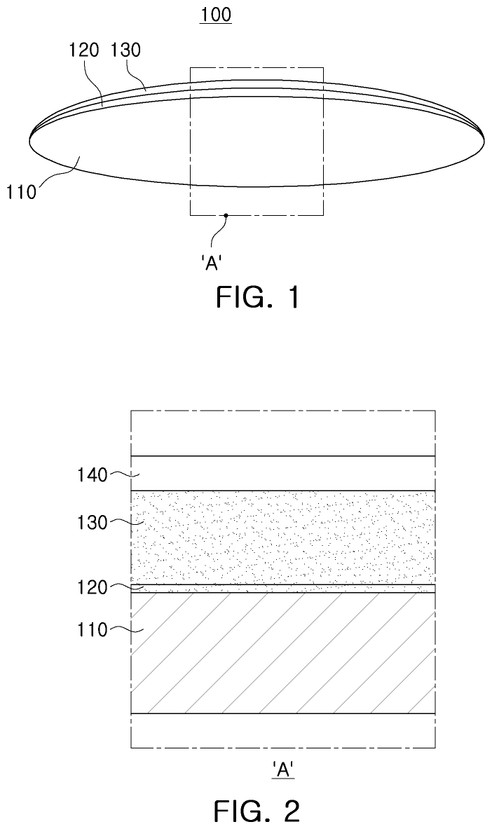

FIG. 1 is a schematic cross-sectional view of an example of a lens according to an embodiment of the present disclosure, and FIG. 2 is a cross-sectional view illustrating an enlarged region of the lens of FIG. 1.

Referring to FIGS. 1 and 2, a lens 100, according to an embodiment of the present disclosure, includes a lens unit 110, an intermediate layer 120, and an AR coating layer.

In the case of the lens unit 110, a shape or type thereof is not limited and may be implemented in the form of a lens that can be used in an optical device such as a camera module, or the like.

Accordingly, the shape of the lens unit 110 may be modified to have a shape other than that illustrated in FIG. 1.

The lens unit 110 may be formed of a plastic resin containing a resin component.

For example, the plastic resin may include at least one component of polycarbonate and polyolefin.

Here, the polyolefin may include at least one of a cycloolefin polymer and a cycloolefin copolymer.

However, the lens unit 110 may be formed of other materials, such as glass.

The AR coating layer is disposed on one surface of the lens unit 110. The AR coating layer can reduce the reflectivity of the lens 100, and thus a flare phenomenon may be reduced or prevented.

In this case, the AR coating layer may include a multilayer structure in which a first coating layer 130 and a second coating layer 140 having different refractive indices are alternately stacked one or more times.

In addition, the first coating layer 130 may be formed by depositing SiO₂ by ALD, and the second coating layer 140 may be formed by depositing Al₂O₃ by ALD, and in this case, a uniform thin film may be formed using such an ALD method.

The intermediate layer 120 may be disposed between the lens unit 110 and the AR coating layer, and may be formed of the same material as a lowermost layer of the first coating layer 130 or the second coating layer 140 constituting the AR coating layer disposed on the lens unit 110 by CVD.

In the drawing of an embodiment, since the lowermost layer of the AR coating layer is a first coating layer, it is described that the intermediate layer is formed of the same material as the first coating layer.

The ALD method has limited precursor gas capable of depositing SiO₂ and has low affinity with a plastic lens, so an interface between the lens unit and the AR coating layer is attached with an adhesive layer formed of Al₂O₃.

However, in an embodiment of the present disclosure, a first coating layer, the lowermost layer of the AR coating layer, is formed of SiO₂, and an intermediate layer serving as an adhesive layer is formed of SiO₂ by using the CVD method instead of ALD to attach the lens unit and the AR coating layer.

The refractive index of Al₂O₃ is 1.61 and the refractive index of SiO₂ is 1.46, which are different from each other. In an embodiment, the first coating layer, the lowermost layer of the AR coating layer, and the intermediate layer, which is an adhesive layer, are formed of the same material, SiO₂. In this case, due to the multilayer structure, the refractive indices thereof do not cross, so that not only the optical design may be simplified, but also the thickness of the AR coating layer may be reduced.

According to an embodiment of the present disclosure, the same material as the lowermost layer of the AR coating layer may be deposited by improving the deposition method to form an intermediate layer between the lens unit to improve adhesion and reduce a change in optical properties, so that deterioration in the optical properties may be improved.

The thickness of the intermediate layer 120 may be 10 to 20 nm. In this case, the thickness of the intermediate layer 120 may be measured using both non-destructive testing and destructive testing.

As an example of non-destructive testing, there are ellipsometers, reflectometers, and the like.

As an example of destructive analysis, TEM analysis may be performed after processing a cross-section of the intermediate layer 120 by focused ion beam (FIB), and the cross-section of the intermediate layer 120 may be taken to include a central portion of the lens unit 110, that is, the thickest region of the lens unit 110.

The thickness of the intermediate layer 120 may be defined as a distance measured in a direction perpendicular to a surface thereof, and may be determined as an average value of values measured in a plurality of regions having equal intervals.

When the thickness of the intermediate layer 120 is less than 10 nm, the thickness of the intermediate layer 120 is deposited too thinly, so the adhesion between the lens unit 110 and the AR coating layer may decrease, which may cause defects.

In addition, when the thickness of the intermediate layer 120 exceeds 20 nm, the thickness of the intermediate layer 120 is excessively thick and the reflectance increases, which may cause a problem in that the optical properties of the product (lens) are deteriorated.

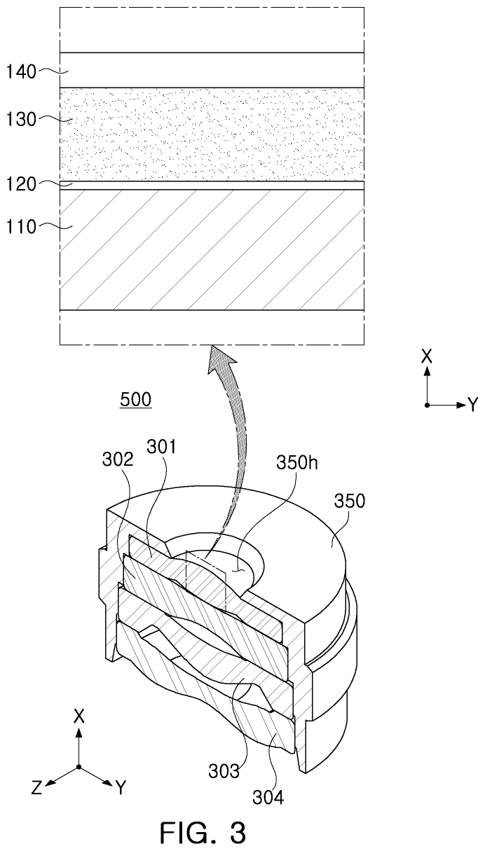

Examples to which the above-described lens is applied will be described with reference to FIGS. 3 to 7.

First, FIG. 3 is a cutaway perspective view schematically illustrating a lens assembly.

In the present embodiment, a lens assembly 500 includes at least one lens 301 to 304.

In the present embodiment, the lens assembly 500 includes four lenses 301 to 304, but the number and/or shape of each of the lenses 301 to 304 may be changed according to desired functions and/or size conditions.

The lens assembly 500 may include a lens barrel 350 having a lens aperture 350h in addition to the plurality of lenses 301 to 304.

The lens barrel 350 may have a hollow cylindrical shape, and a lens aperture 350h for transmitting light may be formed therethrough on one surface of the lens barrel 350.

At least one lens 301 of the plurality of lenses 301 to 304 may employ a lens according to the above-described embodiment.

That is, in the example illustrated, the lens 301 includes an AR coating layer, including the lens unit 110, the intermediate layer 120, the first coating layer 130, and the second coating layer 140.

The lens 301, including the intermediate layer and the AR coating layer, may be disposed on a side on which light is incident, that is, on the outermost side of the lens assembly 500 among the plurality of lenses 301 to 304 in an optical axis direction (X-direction based on the drawing).

Since the lens 301 disposed on the outermost side of the plurality of lenses 301 to 304 has the greatest influence on reliability, reflectivity, and the like, of the lens assembly 500, optical properties of the lens assembly 500 may be improved by forming the lens 301 with the first and second coating layers 130 and 140 on the outside thereof.

In addition, the optical characteristics of the lens assembly 500 may be further improved by applying the same structure as the lens 301 to at least one of the remaining lenses 302 to 304 other than the outermost lens 301.

These various modified structures for the lens assembly 500 may also be applied to portable electronic devices.

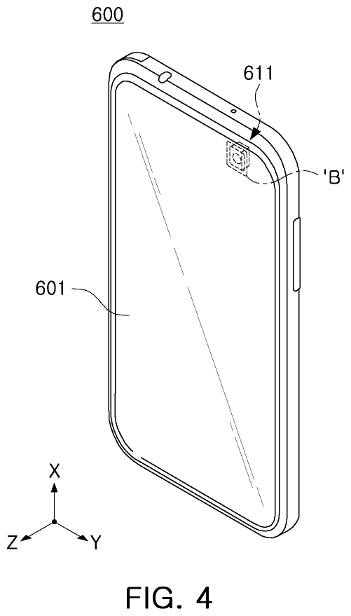

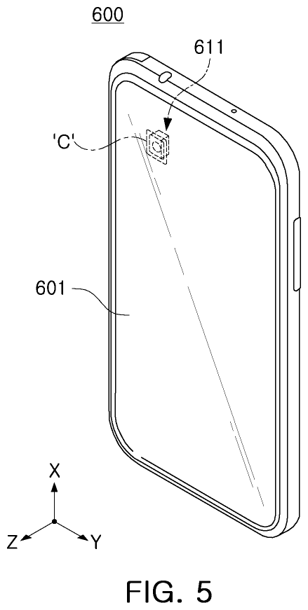

FIGS. 4 and 5 are perspective views schematically illustrating a portable electronic device, respectively illustrating a front portion and a rear portion.

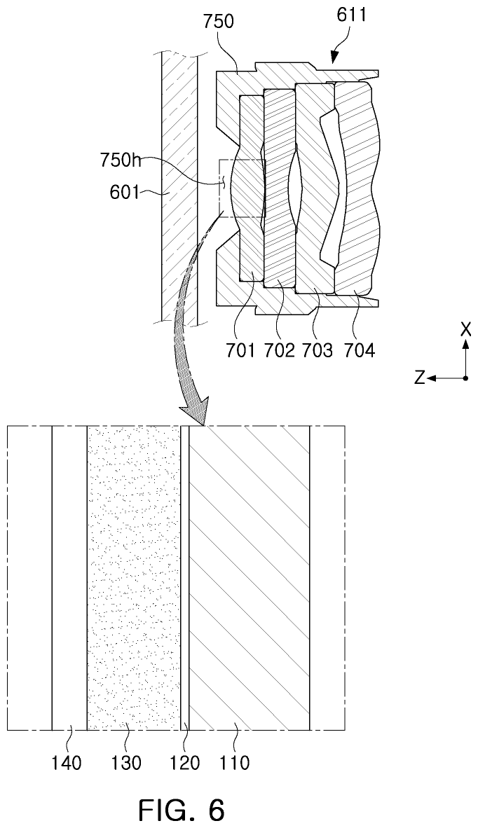

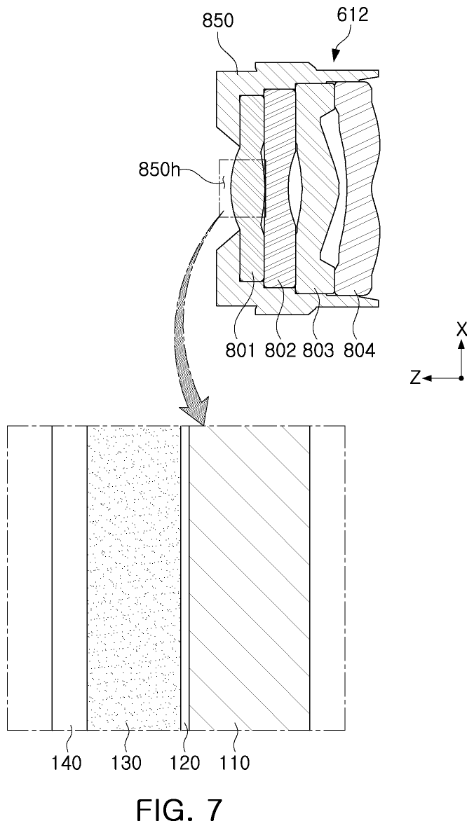

FIGS. 6 and 7 are cross-sectional views illustrating enlarged peripheral regions B and C of a lens assembly in FIGS. 4 and 5, respectively.

As a non-exhaustive example only, a portable electronic device, for example, portable electronic device 600, as described herein may be a mobile device, such as a cellular phone, a smart phone, a wearable smart device (such as a ring, a watch, a pair of glasses, a bracelet, an ankle bracelet, a belt, a necklace, an earring, a headband, a helmet, or a device embedded in clothing), a portable personal computer (PC) (such as a laptop, a notebook, a subnotebook, a netbook, or an ultra-mobile PC (UMPC), a tablet PC (tablet), a phablet, a personal digital assistant (PDA), a digital camera, a portable game console, an MP3 player, a portable/personal multimedia player (PMP), a handheld e-book, a global positioning system

(GPS) navigation device, or a sensor, or a stationary device, such as a desktop PC, a high-definition television (HDTV), a DVD player, a Blu-ray player, a set-top box, or a home appliance, or any other mobile or stationary device configured to perform wireless or network communication. In one example, a wearable device is a device that is designed to be mountable directly on the body of the user, such as a pair of glasses or a bracelet. In another example, a wearable device is any device that is mounted on the body of the user using an attaching device, such as a smart phone or a tablet attached to the arm of a user using an armband, or hung around the neck of the user using a lanyard.

In an example where the portable electronic device is a smart phone, the portable electronic device 600 is a main component and includes a display unit 601, a first lens assembly 611, and a second lens assembly 612.

However, if desired, only one of the first and second lens assemblies 611 and 612 may be used.

In addition to the display unit 601 and the lens assemblies 611 and 612, the other main elements constituting the portable electronic device 600 (e.g., a processing module, a communication module, a touch sensing module, and the like) may have typical configurations known in the art, thus, a detailed description thereof will be omitted.

The first and second lens assemblies 611 and 612 may have the structure described in FIG. 5. Specifically, the first lens assembly 611 may include a lens barrel 750 having a lens aperture 750h in addition to a plurality of lenses 701 to 704.

At least one lens 701, among the plurality of lenses 701 to 704, may employ a lens according to the above-described embodiment.

That is, as illustrated, the lens 701 includes a lens unit 110, an intermediate layer 120, and an AR coating layer.

In this case, a lens 701 including an intermediate layer and an AR coating layer may be disposed on the outermost side of the first lens assembly 611 among the plurality of lenses 701 to 704 in a direction in which light is incident, that is, in an optical axis direction (Z-direction based on the drawing).

Similarly, the second lens assembly 612 may include a lens barrel 850 having a lens aperture 850h in addition to a plurality of lenses 801 to 804.

At least one lens 801, among the plurality of lenses 801 to 804, may employ a lens according to the above-described embodiment.

That is, as illustrated, a low-reflection lens 801 includes a lens unit 110, an intermediate layer 120, and an AR coating layer.

In this case, the lens 801 including the intermediate layer and the AR coating layer may be disposed on the outermost side of the first lens assembly 811 among the plurality of lenses 801 to 804 in a direction in which light is incident, that is, in an optical axis direction (Z-direction based on the drawing).

As illustrated, the first lens assembly 611 may be covered by the display unit 601, for example, may be covered by a tempered glass portion of the display unit 601.

However, when tempered glass covers the first lens assembly 611, the tempered glass may not be a partial component of the display unit 601.

As described above, when the first lens assembly 611 is covered by the display unit 601, or the like, an amount of light incident on the lens may be reduced, so that reflectivity of the first lens assembly 611 may have a greater effect on the performance of the camera module.

In other words, in the case of a front portion of the portable electronic device 600, the first lens assembly 611 may be covered by the display unit 601, which may correspond to a so-called under display camera (UDC) structure.

The UDC structure may have an advantage of reducing camera aperture processing, but as additional tempered glass is disposed on the camera to implement the UDC structure, the amount of light incident on the camera is reduced, which may cause performance degradation.

Therefore, when the reflectivity of the lens is high in the UDC structure, the performance of the camera module may be greatly reduced, and as in the present embodiment, by disposing a lens 701 closest to an incident side, that is the display unit 601, an effect of reducing reflectivity of the first lens assembly 611 may be maximized, and the performance of the camera module including the lens 701 may be improved.

Meanwhile, in the above-described example, a case in which the first lens assembly 611 is covered by the display unit 601 has been described, but depending on the embodiment, the second lens assembly 612 may also be covered with an optical element that may cause light loss, for example, tempered glass, and in this case, an effect of reducing the reflectivity of the second assembly 612 may be more important.

As set forth above, in the case of a lens according to an embodiment of the present disclosure, an intermediate layer may be formed at an interface between a lens unit and an

AR coating layer, and the intermediate layer may be formed of the same material as the lowermost layer of the AR coating layer, thereby having an effect capable of preventing deterioration in adhesion between the lens unit and the AR coating layer without deteriorating the optical properties.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents.

Therefore, in addition to the above and all drawing disclosures, the scope of the disclosure is also inclusive of the claims and their equivalents, i.e., all variations within the scope of the claims and their equivalents are to be construed as being included in the disclosure.

What is claimed is:

1. A lens, comprising:
a lens unit;
an anti-reflective (AR) coating layer, disposed on one surface of the lens unit, comprising a first coating layer and a second coating layer alternately stacked one or more times, wherein a refractive index of the first coating layer is different from a refractive index of the second coating layer; and
an intermediate layer, disposed between the lens unit and the AR coating layer, is formed of a same material as the first coating layer or the second coating layer,
wherein the intermediate layer is disposed on the lens unit by chemical vapor deposition (CVD).

2. The lens of claim 1, wherein the first coating layer is formed by depositing SiO₂ using Atomic Layer Deposition (ALD), and the second coating layer is formed by depositing Al₂O₃ using ALD.

3. The lens of claim 1, wherein the intermediate layer has a thickness of 10 to 20 nm.

4. A lens assembly comprising a plurality of lenses in an optical axis direction, wherein an outermost lens of the plurality of lenses comprises the lens of claim 1.

5. A portable electronic device comprising a display unit configured to show information from the lens assembly of claim 4.

6. A lens assembly comprising a plurality of lenses in an optical axis direction, wherein at least one lens of the plurality of lenses comprises the lens of claim 1.

7. A lens assembly comprising at least one lens, the at least one lens comprising:
a lens unit;
an anti-reflective (AR) coating layer, disposed on one surface of the lens unit, comprising a first coating layer and a second coating layer alternately stacked one or more times, wherein a refractive index of the first coating layer is different from a refractive index of the second coating layer; and
an intermediate layer, disposed between the lens unit and the AR coating layer, is formed of a same material as the first coating layer or the second coating layer,
wherein the intermediate layer is disposed on the lens unit by chemical vapor deposition (CVD).

8. The lens assembly of claim 7, wherein the first coating layer is formed by depositing SiO₂ using Atomic Layer Deposition (ALD), and the second coating layer is formed by depositing Al₂O₃ using ALD.

9. The lens assembly of claim 7, wherein the intermediate layer has a thickness of 10 to 20 nm.

10. The lens assembly of claim 7, wherein the at least one lens is disposed on an outermost side of the lens assembly in an optical axis direction of the at least one lens.

11. A portable electronic device comprising a display unit configured to show information from a lens assembly, the lens assembly comprising at least one lens, and the at least one lens comprising:
a lens unit;
an anti-reflective (AR) coating layer, disposed on one surface of the lens unit, comprising a first coating layer and a second coating layer alternately stacked one or more times, wherein a refractive index of the first coating layer is different from a refractive index of the second coating layer; and
an intermediate layer, disposed between the lens unit and the AR coating layer, is formed of a same material as the first coating layer or the second coating layer,
wherein the intermediate layer is disposed on the lens unit by chemical vapor deposition (CVD).

12. The portable electronic device of claim 11, wherein the at least one lens is disposed on an outermost side of the lens assembly in an optical axis direction of the at least one lens.

13. The portable electronic device of claim 11, wherein the lens assembly is covered by the display unit.

14. The portable electronic device of claim 11, wherein the lens assembly is covered by tempered glass.
